(19) United States
(12) Patent Application Publication
(10) Pub. No.: US 2017/0018623 A1
(43) Pub. Date: Jan. 19, 2017

(54) SEMICONDUCTOR DEVICE AND METHOD OF FABRICATING THE SAME

(71) Applicant: SAMSUNG ELECTRONICS CO., LTD., SUWON-SI (KR)

(72) Inventors: SUNG-DAE SUK, SEOUL (KR); BOM-SOO KIM, SEOUL (KR)

(21) Appl. No.: 14/802,843

(22) Filed: Jul. 17, 2015

(51) Int. Cl. H01L 29/423; H01L 29/06; H01L 29/78

(52) U.S. Cl. CPC H01L 29/42392; H01L 29/785; H01L 29/0673

(57) ABSTRACT

The semiconductor device includes a first wire pattern formed on a substrate and spaced apart from the substrate, the first wire pattern extending in a first direction. A gate electrode surrounds a circumference of the first wire pattern and extends in a second direction. The second direction crosses the first direction. A gate spacer is disposed on opposite sidewalls of the gate electrode, the gate spacer including a first part and a second part. The first part includes a top portion and a bottom portion spaced apart from each other. The second part is disposed at opposite sides of the first part in the second direction. The second part directly contacts the bottom portion of the first part.

### TECHNICAL FIELD

The present inventive concept relates to a semiconductor device, and a method of fabricating the same.

### DISCUSSION OF THE RELATED ART

A scaling technique for increasing the density of a semiconductor device may include a gate all around structure. A gate all around structure includes a silicon body shaped of a nanowire formed on a substrate, and a gate formed to surround the silicon body.

Since the gate all around structure uses a three-dimensional channel, scaling may be achieved. In addition, current controlling capability may be improved without increasing a length of the gate. Further, a short channel effect (SCE), in which a potential of a channel region may be affected by a drain voltage, may be effectively suppressed.

### SUMMARY

The present inventive concept includes a semiconductor device in which an insulation pattern may be disposed between a gate electrode and a source/drain, in a transistor having a gate all around structure.

According to an exemplary embodiment of the present inventive concept, a semiconductor device includes a first wire pattern formed on a substrate and spaced apart from the substrate, the first wire pattern extending in a first direction. A gate electrode surrounds a circumference of the first wire pattern and extends in a second direction. The second direction crosses the first direction. A gate is spacer disposed on opposite sidewalls of the gate electrode, the gate spacer including a first part and a second part. The first part includes a top portion and a bottom portion spaced apart from each other. The second part is disposed at opposite sides of the first part in the second direction. The second part directly contacts the bottom portion of the first part.

According to an exemplary embodiment of the present inventive concept, the first wire pattern may pass through the first part of the gate spacer.

According to an exemplary embodiment of the present inventive concept, the top portion of the first part of the gate spacer may include a material having a first dielectric constant and the bottom portion of the first part of the gate spacer includes a material having a second dielectric constant. The second dielectric constant may be different from the first dielectric constant.

According to an exemplary embodiment of the present inventive concept, the top portion of the first part of the gate spacer and the second part of the gate spacer may form an integral structure.

According to an exemplary embodiment of the present inventive concept, a topmost part of the first wire pattern may contact the top portion of the first part of the gate spacer and a bottommost part of the first wire pattern may contact the bottom portion of the first part of the gate spacer.

According to an exemplary embodiment of the present inventive concept, the semiconductor device may further include a second wire pattern on the substrate and spaced apart from the substrate. A first distance between the second wire pattern and the substrate may be greater than a second distance between the first wire pattern and the substrate. The bottom portion of the first part of the gate spacer may be disposed between the first wire pattern and the second wire pattern.

According to an exemplary embodiment of the present inventive concept, the semiconductor device may further include a source/drain connected to the first wire pattern at opposite sides of the gate electrode. The source/drain may include an epitaxial layer.

According to an exemplary embodiment of the present inventive concept, the semiconductor device may further include a gate insulation layer formed along the circumference of the first wire pattern and sidewalls of the gate spacer.

According to an exemplary embodiment of the present inventive concept, the semiconductor device may further include a source/drain connected to the first wire pattern at opposite sides of the gate electrode. The source/drain need not contact the gate insulation layer.

According to an exemplary embodiment of the present inventive concept, the gate spacer may include a through-hole. The first wire pattern may pass through the through hole. First sides facing each other in the second direction in the through-hole may be defined by the second part of the gate spacer. At least one of second sides connecting the first sides in the through-hole may be defined by the bottom portion of the first part of the gate spacer.

According to an exemplary embodiment of the present inventive concept, a semiconductor device includes a wire pattern formed on a substrate and spaced apart from the substrate, the wire pattern extending in a first direction. A gate electrode surrounds a circumference of the wire pattern and extends in a second direction. The second direction crosses the first direction. A gate spacer is disposed on opposite sidewalls of the gate electrode. The gate spacer contacts the entire circumference of a termination part of the wire pattern. A gate insulation layer is formed along the circumference of the wire pattern and sidewalls of the gate spacer.

According to an exemplary embodiment of the present inventive concept, the gate spacer may include a first part including a material having a first dielectric constant and a second part including a material having a second dielectric constant. The second dielectric constant may be smaller than the first dielectric constant.

According to an exemplary embodiment of the present inventive concept, the wire pattern may contact the second part of the gate spacer.

According to an exemplary embodiment of the present inventive concept, the gate spacer may include a through-hole. The wire pattern may pass through the through-hole.

According to an exemplary embodiment of the present inventive concept, the wire pattern may extend in the first direction past the gate insulation layer formed on the sidewalls of the gate electrode.

According to an exemplary embodiment of the present inventive concept, a semiconductor device includes a wire pattern extending in a first direction and spaced apart from a substrate. A gate electrode extends in a second direction that crosses the first direction. The gate electrode surrounds a circumference of the wire pattern. A gate spacer is disposed on opposite termination parts of the wire pattern, the gate spacer including a through-hole. At least one of the opposite termination parts of the wire pattern passes through the through-hole.

According to an exemplary embodiment of the present inventive concept, the gate spacer may include a first part and a second part. The first part may include a top portion and a bottom portion spaced apart from each other. The second part may be disposed in the second direction at opposite sides of the first part. The second part may directly contact the bottom portion of the first part.

According to an exemplary embodiment of the present inventive concept, the top portion of the first part of the gate spacer may include a material having a first dielectric constant and the bottom portion of the first part of the gate spacer may include a material having a second dielectric constant. The second dielectric constant may be different from the first dielectric constant.

According to an exemplary embodiment of the present inventive concept, the top portion of the first part of the gate spacer and the second part of the gate spacer may form a connected structure.

According to an exemplary embodiment of the present inventive concept, the semiconductor device may further include a gate insulation layer formed along the circumference of the wire pattern and sidewalls of the gate spacer. The wire pattern may extend in the first direction past the gate insulation layer formed on the sidewalls of the gate electrode.

### BRIEF DESCRIPTION OF THE DRAWINGS

The above and other features and aspects of the present inventive concept will become more apparent by describing in detail exemplary embodiments thereof with reference to the accompanying drawings in which:

FIG. 1 is a perspective view for explaining a semiconductor device, according to an exemplary embodiment of the present inventive concept;

FIG. 2 is a cross-sectional view of the semiconductor device shown in FIG. 1, taken along line A-A of FIG. 1, according to an exemplary embodiment of the present inventive concept;

FIG. 3 is a cross-sectional view of the semiconductor device shown in FIG. 1, taken along line B-B of FIG. 1, according to an exemplary embodiment of the present inventive concept;

FIG. 4A is a cross-sectional view of the semiconductor device shown in FIG. 1, taken along line C-C of FIG. 1, according to an exemplary embodiment of the present inventive concept. FIG. 4B illustrates a gate spacer of FIG. 4A, according to an exemplary embodiment of the present inventive concept;

FIGS. 5 to 6B are views for explaining a semiconductor device according to an exemplary embodiment of the present inventive concept;

FIGS. 7 to 9 are cross-sectional views for explaining a semiconductor device according to an exemplary embodiment of the present inventive concept;

FIG. 10 is a perspective view for explaining a semiconductor device according to an exemplary embodiment of the present inventive concept;

FIG. 11 is a cross-sectional view of the semiconductor device shown in FIG. 1, taken along line A-A of FIG. 10, according to an exemplary embodiment of the present inventive concept;

FIG. 12 is a cross-sectional view of the semiconductor device shown in FIG. 1, taken along line B-B of FIG. 10, according to an exemplary embodiment of the present inventive concept;

FIGS. 13 to 23B illustrate intermediate process steps in a method of manufacturing a semiconductor device according to an exemplary embodiment of the present inventive concept;

FIG. 24 is a block diagram of an electronic system including semiconductor devices manufactured according to one or more methods of manufacturing a semiconductor device, according to one or more exemplary embodiments of the present inventive concept; and

FIGS. 25 and 26 illustrate exemplary semiconductor systems which may use semiconductor devices according to one or more exemplary embodiments of the present inventive concept.

### DETAILED DESCRIPTION OF THE EMBODIMENTS

The present inventive concept will now be described more fully with reference to the accompanying drawings, in which exemplary embodiments of the present inventive concept are shown. The present inventive concept may, however, be embodied in different forms and is not limited to the exemplary embodiments thereof set forth herein. Exemplary embodiments of the present inventive concept are described to convey the scope of the present inventive concept to those skilled in the art. The same reference numbers may indicate the same components throughout the specification. In the attached figures, the thickness of layers and regions may be exaggerated for clarity.

It will be understood that when an element or layer is referred to as being “connected to,” or “coupled to” another element or layer, it may be directly connected to or coupled to another element or layer, or intervening elements or layers may be present. In contrast, when an element is referred to as being “directly connected to” or “directly coupled to” another element or layer, there are no intervening elements or layers present. Like numbers may refer to like elements. As used herein, the term “and/or” may include any and all combinations of one or more of the referred to elements.

It will also be understood that when a layer is referred to as being “on” another layer or substrate, it may be directly on the other layer or substrate, or intervening layers may be present.

It will be understood that, although the terms first, second, or the like may be used to describe various elements, the elements should not be limited to the descriptions thereof. These terms are only used to distinguish one element from another element. For example, a first element, a first component or a first section may be described as a second element, a second component or a second section without departing from the teachings of the present inventive concept.

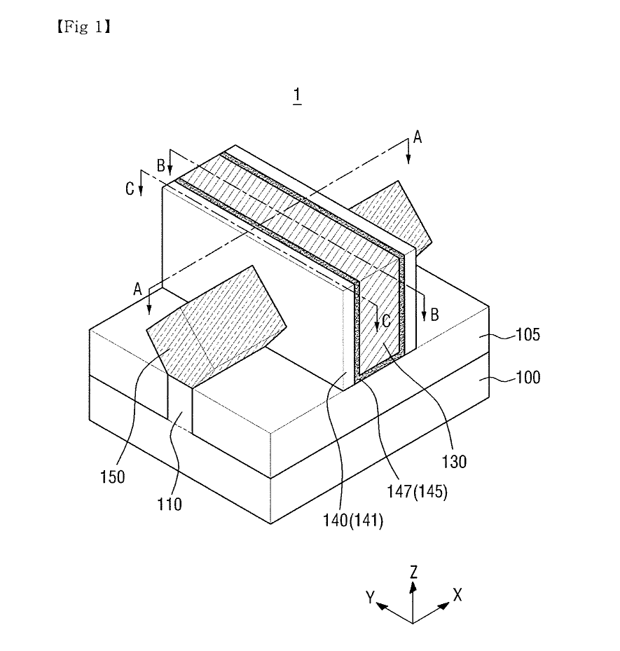

A semiconductor device according to an exemplary embodiment of the present inventive concept will be described with reference to FIGS. 1 to 4B.

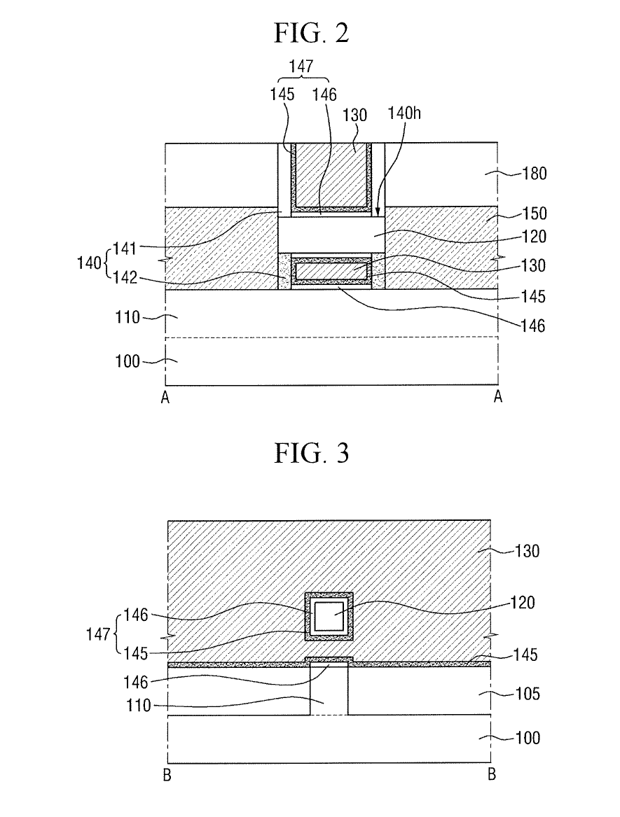

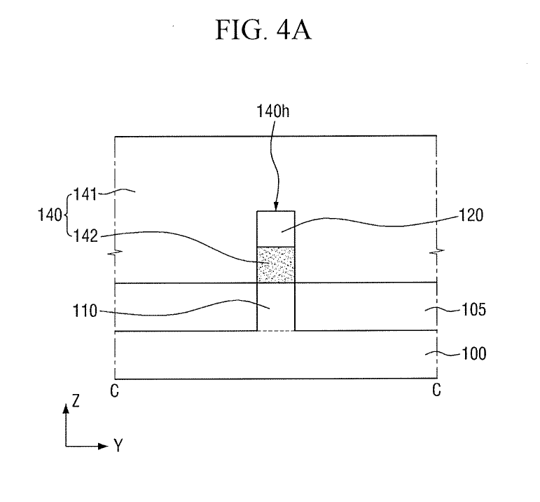

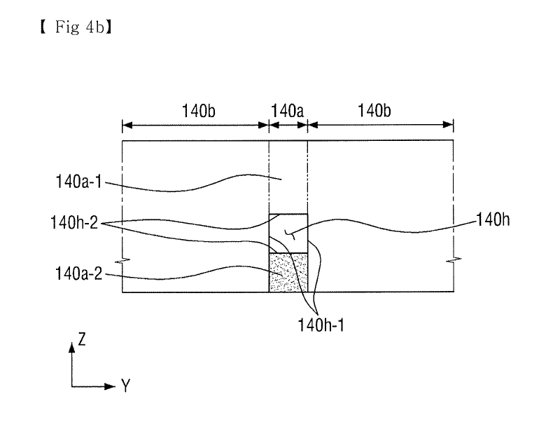

FIG. 1 is a perspective view for explaining a semiconductor device, according to an exemplary embodiment of the present inventive concept. FIG. 2 is a cross-sectional view of the semiconductor device shown in FIG. 1, taken along line A-A of FIG. 1, according to an exemplary embodiment of the present inventive concept. FIG. 3 is a cross-sectional view of the semiconductor device shown in FIG. 1, taken along line B-B of FIG. 1, according to an exemplary embodiment of the present inventive concept. FIG. 4A is a cross-sectional view of the semiconductor device shown in FIG. 1, taken along line C-C of FIG. 1, according to an exemplary embodiment of the present inventive concept. FIG. 4B illustrates a gate spacer of FIG. 4A, according to an exemplary embodiment of the present inventive concept. For clarity, an interlayer insulating layer 180 is not illustrated in FIG. 1.

Referring to FIGS. 1 to 4B, the semiconductor device 1, according to an exemplary embodiment of the present inventive concept, may include a fin type pattern 110, a first wire pattern 120, a gate electrode 130, a gate spacer 140 and a source/drain 150.

The substrate 100 may include, for example, bulk silicon or a silicon-on-insulator (SOI). Alternatively, the substrate 100 may be a silicon substrate, or a substrate made of other materials such as, for example, germanium, silicon germanium, indium antimonide, lead telluride compound, indium arsenide, indium phosphide, gallium arsenide, or gallium antimonide. In addition, the substrate 100 may include an epitaxial layer formed on a base substrate.

The fin type active pattern 110 may protrude from the substrate 100. The field insulation layer 105 may surround at least portions of sidewalls of the fin type active pattern 110. The fin type pattern 110 may be defined by the field insulation layer 105.

The field insulation layer 105 may include, for example, an oxide layer, a nitride layer, an oxynitride layer, or a combination of an oxide layer, a nitride layer, and an oxynitride layer.

FIG. 1 shows that the sidewalls of the fin type pattern 110 may be entirely surrounded by the field insulation layer 105. However, exemplary embodiments of the present inventive concept are not limited thereto.

The fin type pattern 110 may extend lengthwise in a first direction X. For example, the fin type pattern 110 may have long sides extending in the first direction X and short sides extending in a second direction Y.

The fin type pattern 110 may be formed by etching a portion of the substrate 100 or may include an epitaxial layer grown from the substrate 100. The fin type pattern 110 may include, for example, silicon or germanium, which are semiconductor material elements. In addition, the fin type pattern 110 may include a compound semiconductor, including, for example, a Group IV-IV compound semiconductor or a Group III-V compound semiconductor.

Examples of the Group IV-IV compound semiconductor may include a binary compound or a ternary compound including at least two elements selected from the group consisting of carbon (C), silicon (Si), germanium (Ge), and tin (Sn). Examples of the Group IV-IV compound semiconductor may also include compounds doped with Group IV elements.

The group III-V compound semiconductor may include, for example, a binary compound, a ternary compound or a quaternary compound, prepared by combining at least one group III element of aluminum (Al), gallium (Ga) and indium (In) with at least one group V element of phosphorus (P), arsenic (As) and antimony (Sb).

In the semiconductor devices, according to exemplary embodiments of the present inventive concept, the fin type pattern 110 may include silicon.

The first wire pattern 120 may be formed on the substrate 100 and may be spaced apart from the substrate 100. The first wire pattern 120 may extend in the first direction X.

For example, first wire pattern 120 may be formed on the fin type pattern 110 and may be spaced apart from the fin type pattern 110. The first wire pattern 120 may overlap with the fin type pattern 110. The first wire pattern 120 need not be formed on the field insulation layer 105 but may be formed on the fin type pattern 110.

In FIG. 3, a width of the first wire pattern 120 in the second direction Y is illustrated as being the same as the width of the fin type pattern 110 in the second direction Y. However, exemplary embodiments of the present inventive concept are not limited thereto. In addition, in FIG. 3, the first wire pattern 120 is illustrated as having a rectangular cross-section, according to an exemplary embodiment of the inventive concept. However, the rectangular cross-section of the first wire pattern 120 is provided to illustrate a cross-section of the first wire pattern 120, according to an exemplary embodiment of the present inventive concept. Exemplary embodiments of the present inventive concept are not limited thereto. For example, corners of the first wire pattern 120 may be rounded, for example, by trimming.

The first wire pattern 120 may be used as a channel region of a transistor. The first wire pattern 120 may vary according to the semiconductor device 1 being a p-type metal oxide semiconductor (PMOS) or an n-type metal oxide semiconductor (NMOS) transistor. However, exemplary embodiments of the present inventive concept are not limited thereto.

In addition, the first wire pattern 120 may include a material that is the same as or different from the fin type pattern 110. However, in semiconductor devices according to one or more exemplary embodiments of the present inventive concept, the first wire pattern 120 may include silicon.

The gate electrode 130 may be formed on the field insulation layer 105 and the fin type pattern 110. The gate electrode 130 may extend in the second direction Y.

The gate electrode 130 may surround the circumference of the first wire pattern 120. The wire pattern 120 may be spaced apart from a top surface of the fin type pattern 110. The gate electrode 130 may also be formed in a space between the first wire pattern 120 and the fin type pattern 110.

The gate electrode 130 may include a conductive material. The gate electrode 130 may be formed as a single layer, as illustrated in FIG. 2 and FIG. 3, but exemplary embodiments of the present inventive concept are not limited thereto. For example, the gate electrode 130 may include a work function conductive layer controlling a work function and a filling conductive layer filling a space formed by the work function conductive layer.

The gate electrode 130 may include, for example, at least one of TiN, WN, TaN, Ru, TiC, TaC, Ti, Ag, Al, TiAl, TiAlN, TiAlC, TaCN, TaSiN, Mn, Zr, W, and Al. Alternatively, the gate electrode 130 may include a non-metal material, such as Si or SiGe. The gate electrode 130 may be formed by, for example, a replacement process. However, exemplary embodiments of the present inventive concept are not limited thereto.

The gate spacer 140 may be formed on sidewalls of the first gate electrode 130 extending in the second direction Y. The gate spacer 140 may be formed on opposite sides of the first wire pattern 120. The opposite sides of the first wire pattern 120 may face each other.

The gate spacer 140 may be disposed at opposite termination parts of the first wire pattern 120. Each gate spacer 140 may include a through-hole 140h.

The first wire pattern 120 may pass the gate spacer 140. The first wire pattern 120 may extend, in the first direction, past (e.g., be longer than) the gate insulation layer 147 formed on the sidewalls of the gate electrode 130. The first wire pattern 120 may pass through the through-hole 140h. The gate spacer 140 may contact the entire circumference of the termination parts of the first wire pattern 120.

When the corners of the first wire pattern 120, surrounded by the gate electrode 130, are rounded by trimming, a cross section of the termination part of the first wire pattern 120 making contact with the gate spacer 140 may be different from a cross-section of the first wire pattern 120, surrounded by the gate electrode 130.

The gate spacer 140 may include an external spacer 141 and an internal spacer 142. The external spacer 141 may directly contact the internal spacer 142. The internal spacer 142 may be disposed between a top surface of the fin type pattern 110 and the first wire pattern 120. A surface of the internal spacer 142 may contact the top surface of the fin type pattern 110. On a YZ cross-section, the internal spacer 142 may be surrounded by the first wire pattern 120 and the external spacer 141.

The through-hole 140h of the gate spacer 140 may be defined by the external spacer 141 and the internal spacer 142. The termination part of the first wire pattern 120 may contact the external spacer 141 and the internal spacer 142.

In FIG. 4B, the through-hole 140h may include first sides 140h-1 facing each other in a second direction Y and second sides 140h-2 facing each other in a third direction Z. The second sides 140h-2 of the through-hole 140h may connect with the facing first sides 140h-1 of the through-hole 140h.

In semiconductor devices, according to exemplary embodiments of the present inventive concept, at least one of the second sides 140h-2 of the through-hole 140h may be defined by the internal spacer 142. However, the first sides 140h-1 of the through-hole 140h may be defined by the external spacer 141.

Three sides of the through-hole 140h, for example, two first sides 140h-1 of the through-hole 140h and one second side 140h-2 of the through-hole 140h may be defined by the external spacer 141. A side 140h-2 of the through-hole 140h may be defined by the internal spacer 142.

For example, the first sides 140h-1 of the through-hole 140h may be defined by the external spacer 141. One of the second sides 140h-2 of the through-hole 140h may be defined by the external spacer 141. The other second side 140h-2 of the through-hole 140h may be defined by the internal spacer 142.

The external spacer 141 and the internal spacer 142 may include different materials. When the external spacer 141 includes a material having a first dielectric constant and the internal spacer 142 includes a material having a second dielectric constant, the first dielectric constant and the second dielectric constant may be different from each other.

In the semiconductor device according to an exemplary embodiment of the present inventive concept, the first dielectric constant of the material included in the external spacer 141 may be greater than the second dielectric constant of the material included in the internal spacer 142. Since the second dielectric constant is smaller than the first dielectric constant, fringing capacitance between the gate electrode 130 and the source/drain 150 may be reduced.

The external spacer 141 may include, for example, at least one of silicon nitride (SiN), silicon oxynitride (SiON), silicon oxide (SiO₂), silicon carbon oxynitride (SiOCN) and combinations thereof. The internal spacer 142 may include, for example, at least one of silicon nitride (SiN), silicon oxynitride (SiON), silicon oxide (SiO₂), silicon carbon oxynitride (SiOCN) and combinations thereof. A low-k material may be a material having a smaller dielectric constant than silicon oxide.

According to an exemplary embodiment of the present inventive concept, the gate spacer 140 may include a first part 140a and a second part 140b. The second part 140b of the gate spacer 140 may be disposed at opposite sides of the first part 140a of the gate spacer 140 in the second direction Y.

The first part 140a of the gate spacer 140 may be a part in which the first wire pattern 120 passes through. The second part 140b of the gate spacer 140 may be a part in which the first wire pattern 120 does not pass through. The through-hole 140h of the gate spacer 140 may be included in the first part 140a of the gate spacer 140.

The second part 140b of the gate spacer 140 may include the external spacer 141. However, the first part 140a of the gate spacer 140 may include both of the external spacer 141 and the internal spacer 142. The first part 140a of the gate spacer 140 may include a top portion 140a-1 and a bottom portion 140a-2.

The top portion 140a-1 of the first part 140a of the gate spacer 140 may include a portion of the external spacer 141. The bottom portion 140a-2 of the first part 140a of the gate spacer 140 may include the internal spacer 142. A height ranging from a top surface of the substrate 100 to the top portion 140a-1 of the first part 140a of the gate spacer 140 may be greater than a height ranging from the top surface of the substrate 100 to the bottom portion 140a-2 of the first part 140a of the gate spacer 140.

In the semiconductor devices according to the exemplary embodiments of the present inventive concept, at least one of the second sides 140h-2 of the through-hole 140h may be defined by the bottom portion 140a-2 of the second part 140b of the gate spacer 140. The bottom portion 140a-2 of the second part 140b of the gate spacer 140 may be the internal spacer 142. However, the first sides 140h-1 of the through-hole 140h may be defined by the top portion 140a-1 of the first part 140a of the gate spacer 140. The top portion 140a-1 of the first part 140a of the gate spacer 140 may be the external spacer 141.

The bottom portion 140a-2 of the first part 140a of the gate spacer 140 may make direct contact with the second part 140b of the gate spacer 140. In addition, the second part 140b of the gate spacer 140 and the top portion 140a-1 of the first part 140a of the gate spacer 140 may be included in the external spacer 141. Therefore, the second part 140b of the gate spacer 140 and the top portion 140a-1 of the first part 140a of the gate spacer 140 may constitute (e.g., form) one connected structure.

On a part where the gate spacer 140 and the first wire pattern 120 of a semiconductor device overlap, according to an exemplary embodiment of the present inventive concept, there need not be a layer (e.g., element) intervening between the topmost part of the first wire pattern 120 and the external spacer 141. Further, the topmost part of the first wire pattern 120 may make contact with the top portion 140a-1 of the first part 140a of the gate spacer 140.

In the first part 140a of the gate spacer 140, the bottommost part of the first wire pattern 120 may make contact with the bottom portion 140a-2 of the first part 140a of the gate spacer 140. The topmost part of the first wire pattern 120 may make contact with the top portion 140a-1 of the first part 140a of the gate spacer 140.

Thus, in the first part 140a of the gate spacer 140, the bottommost part of the first wire pattern 120 may make contact with the internal spacer 142 and the topmost part of the first wire pattern 120 may make contact with the external spacer 141.

The gate insulation layer 147 may be formed between the first wire pattern 120 and the gate electrode 130. In addition, the gate insulation layer 147 may be formed between the field insulation layer 105 and the gate electrode 130. The gate insulation layer 147 may be formed between the fin type pattern 110 and the gate electrode 130. The gate insulation layer 147 may also be formed between the gate spacer 140 and the gate electrode 130.

The gate insulation layer 147 may include, for example, an interfacial layer 146 and a high-k insulation layer 145. However, exemplary embodiments of the present inventive concept are not limited thereto. For example, the interfacial layer 146 need not be included in the gate insulation layer 147 depending on the material of the first wire pattern 120.

Since the interfacial layer 146 may be formed along the circumference of the first wire pattern 120, the interfacial layer 146 may be formed between the first wire pattern 120 and the gate electrode 130. Also, the interfacial layer 146 may be formed between the fin type pattern 110 and the gate electrode 130. On the other hand, the high-k insulation layer 145 may be formed between the first wire pattern 120 and the gate electrode 130. The high-k insulation layer 145 may be formed between the fin type pattern 110 and the gate electrode 130. The high-k insulation layer 145 may be formed between the field insulation layer 105 and the gate electrode 130. The high-k insulation layer 145 may be formed between the gate spacer 140 and the gate electrode 130.

The gate insulation layer 147 may be formed along the circumference of the first wire pattern 120. The gate insulation layer 147 may be formed along a top surface of the field insulation layer 105. The gate insulation layer 147 may be formed along a top surface of the fin type pattern 110. In addition, the gate insulation layer 147 may be formed along sidewalls of the gate spacer 140. For example, the gate insulation layer 147 may be formed along sidewalls of the external spacer 141 and along sidewalls of the internal spacer 142.

When the first wire pattern 120 includes silicon, the interfacial layer 146 may include a silicon oxide layer. In this case, the interfacial layer 146 may be formed on the circumference of the first wire pattern 120 and on the top surface of the fin type pattern 110. However, when the first wire pattern 120 includes silicon, the interfacial layer 146 need not be formed along the sidewalls of the gate spacer 140.

The high-k insulation layer 145 may include a high-k material having a higher dielectric constant than a silicon oxide layer. The high-k material may include, for example, one or more of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, the composition of the high-k material is not limited thereto.

When the interfacial layer 146 is not provided, the high-k insulation layer 145 may include not only the high-k material, but the high-k insulation layer 145 may also include silicon oxide, silicon oxynitride or silicon nitride.

In FIGS. 1 and 2, the first wire pattern 120 may extend in the first direction X past the gate insulation layer 147, wherein the gate insulation layer 147 may be formed on the sidewalls of the gate electrode 130. For example, the first wire pattern 120 may extend in the first direction X past the high-k insulation layer 145. The termination part of the protruding first wire pattern 120 may pass the gate spacer 140 through the through-hole 140h.

The source/drain 150 may be formed at opposite sides of the gate electrode 130. The source/drain 150 may be formed on the fin type pattern 110. The source/drain 150 may include an epitaxial layer formed on the top surface of the fin type pattern 110.

An outer circumferential surface of the source/drain 150 may have various shapes. For example, the outer circumferential surface of the source/drain 150 may have a shape of a diamond, a circle or a rectangle. In FIG. 1, the source/drain 150 having a diamond shape (e.g., a pentagonal or hexagonal shape) is exemplarily illustrated. However, exemplary embodiments of the inventive concept are not limited thereto.

The source/drain 150 may be directly connected to the first wire pattern 120, wherein the first wire pattern 120 may be used as a channel region. For example, the source/drain 150 may be directly connected to the first wire pattern 120, the first wire pattern 120 having passed the through-hole 140h of the gate spacer 140.

However, the source/drain 150 need not make direct contact with the gate insulation layer 147. The gate spacer 140 may be positioned (e.g., disposed) between the source/drain 150 and the gate insulation layer 147. For example, since one sidewall of the internal spacer 142 makes contact with the gate insulation layer 147 and the other sidewall of the internal spacer 142 makes contact with the source/drain 150, the source/drain 150 and the gate insulation layer 147 need not contact each other between the first wire pattern 120 and the substrate 100. In addition, since the external spacer 141 makes contact with the topmost part of the first wire pattern 120, the source/drain 150 and the gate insulation layer 147 need not contact each other on the first wire pattern 120.

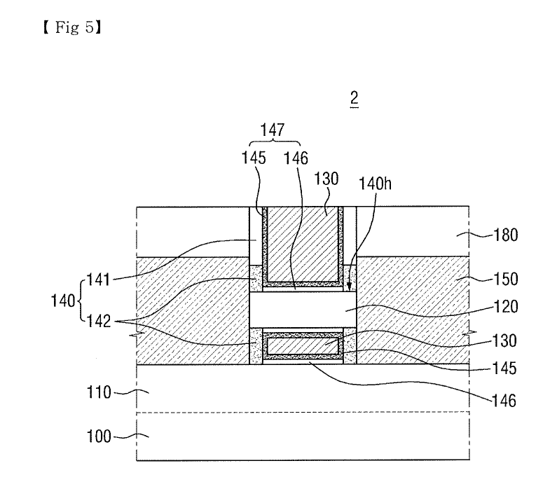

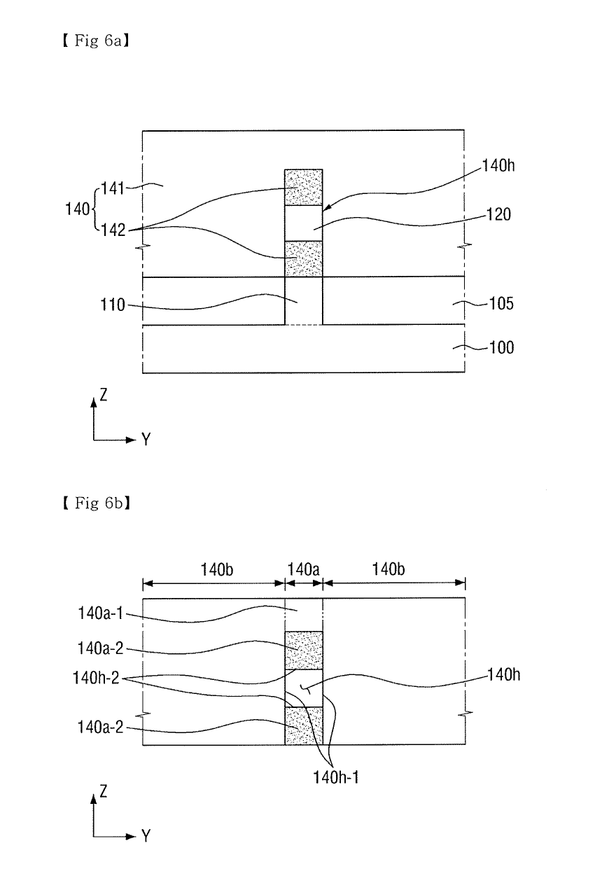

A semiconductor device, according to an exemplary embodiment of the present inventive concept will be described with reference to FIGS. 5 to 6B. For brevity, the following description will focus on differences between an exemplary embodiment of the present inventive concept and the exemplary embodiment of the present inventive concept described with reference to FIGS. 1 to 4B.

FIGS. 5 to 6B are views for explaining a semiconductor device according to an exemplary embodiment of the present inventive concept.

FIG. 5 is a cross-sectional view taken along the line A-A of FIG. 1, according to an exemplary embodiment of the present inventive concept. FIG. 6A is a cross-sectional view taken along the line C-C of FIG. 1, according to an exemplary embodiment of the present inventive concept. FIG. 6C illustrates a gate spacer of FIG. 6A, according to an exemplary embodiment of the present inventive concept.

Referring to FIGS. 5 to 6B, in the semiconductor device 2, according to an exemplary embodiment of the present inventive concept, a bottom portion 140a-2 of a first part 140a of the gate spacer 140 may include a plurality of insulation patterns spaced apart from each other in a third direction Z.

Accordingly, a topmost part of a first wire pattern 120 may make contact with the top portion 140a-1 of the first part 140a of the gate spacer 140. Also, a bottommost part of a first wire pattern 120 may make contact with the bottom portion 140a-2 of the first part 140a of the gate spacer 140.

The topmost part of the first wire pattern 120 and the bottommost part of the first wire pattern 120 may make contact with an internal spacer 142. In the first part 140a of the gate spacer 140, the internal spacer 142 may include a material having a smaller dielectric constant than a dielectric constant of an external spacer 141, and the internal spacer 142 may be positioned (e.g., disposed) on and under the first wire pattern 120.

A through-hole 140h may include two sides 140h-1 defined by the external spacer 141, and two sides 140h-2 defined by the internal spacer 142.

In a semiconductor device, according to an exemplary embodiment of the present inventive concept, the first sides 140h-1 of the through-hole 140h facing each other in a second direction Y may be defined by the external spacer 141, and the second sides 140h-2 of the through-hole 140h facing each other in a third direction Z may be defined by the internal spacer 142.

A semiconductor device according to an exemplary embodiment of the present inventive concept will be described with reference to FIG. 1 and FIGS. 7 to 9. For brevity, the following description will focus on differences between an exemplary embodiment of the present inventive concept and the exemplary embodiment of the inventive concept described with reference to FIGS. 1 to 4B.

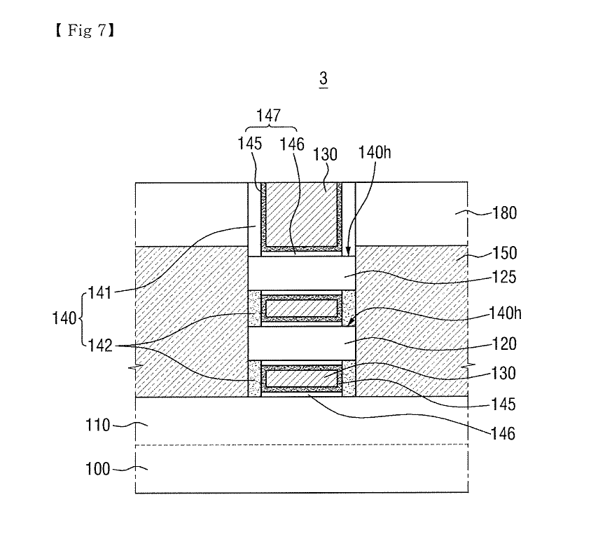

FIGS. 7 to 9 are cross-sectional views for explaining a semiconductor device according to an exemplary embodiment of the present inventive concept.

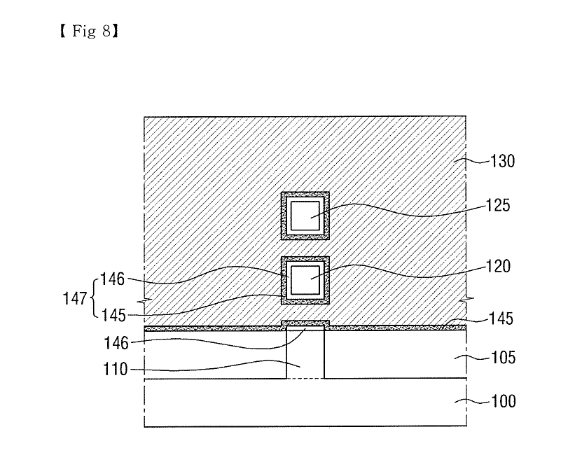

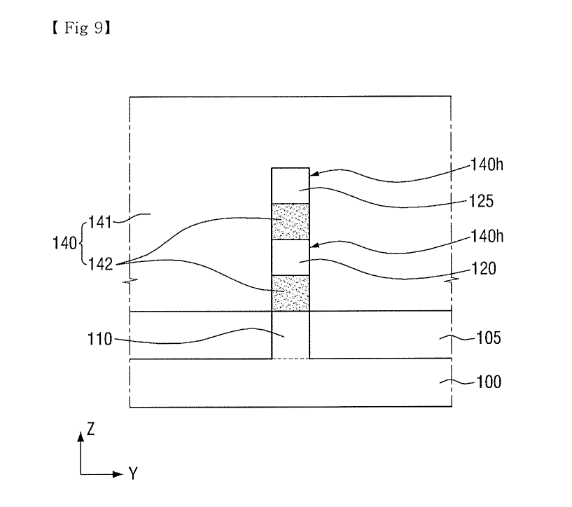

FIG. 7 is a cross-sectional view taken along the line A-A of FIG. 1, according to an exemplary embodiment of the present inventive concept. FIG. 8 is a cross-sectional view taken along the line B-B of FIG. 1, according to an exemplary embodiment of the present inventive concept. FIG. 9 is a cross-sectional view taken along the line C-C of FIG. 1, according to an exemplary embodiment of the present inventive concept.

Referring to FIGS. 7 to 9, the semiconductor device 3 according to an exemplary embodiment of the present inventive concept may further include a second wire pattern 125.

The second wire pattern 125 may be formed on the substrate 100 and may be spaced apart from the substrate 100. The second wire pattern 125 may extend in the first direction X.

A distance between the second wire pattern 125 and the substrate 100 may be greater than a distance between the first wire pattern 120 and substrate 100. For example, a distance measured from a top surface of the fin type pattern 110 to the second wire pattern 125 may be greater than a distance measured from the top surface of the fin type pattern 110 to the first wire pattern 120.

The second wire pattern 125 may overlap with the fin type pattern 110. The second wire pattern 125 need not be formed on the field insulation layer 105 but may be formed on the fin type pattern 110.

The second wire pattern 125 may be used as a channel region of a transistor. Therefore, the second wire pattern 125 may include the same material as the first wire pattern 120.

The gate electrode 130 may surround the circumference of the second wire pattern 125. The gate electrode 130 may be formed in a space between the first wire pattern 120 and the second wire pattern 125.

The gate spacer 140 may be disposed at opposite termination parts of the first wire pattern 120 and opposite termination parts of the second wire pattern 125. Each gate spacer 140 may include a plurality of through-holes 140h.

The second wire pattern 125 may pass through the gate spacer 140. The second wire pattern 125 may pass through one of the plurality of through-holes 140h. The circumference of the termination part of the second wire pattern 125 may entirely contact the gate spacer 140.

When corners of the second wire pattern 125 surrounded by the gate electrode 130 are rounded by trimming, like in the first wire pattern 120, a cross-section of a termination part of the second wire pattern 125 contacting the gate spacer 140 and a cross-section of the second wire pattern 125 surrounded by the gate electrode 130 may be different from each other.

An internal spacer 142 may be disposed (e.g., positioned) between a top surface of the fin type pattern 110 and the first wire pattern 120 and may make surface contact with the top surface of the fin type pattern 110. The internal spacer 142 may also be disposed between the first wire pattern 120 and the second wire pattern 125. Thus, the internal spacer 142 may include a plurality of insulation patterns spaced apart from each other in the third direction Z.

In FIG. 7, the topmost part of the second wire pattern 125 may contact the external spacer 141 and the bottommost part of the second wire pattern 125 may contact the top portion of the internal spacer 142. However, exemplary embodiments of the present disclosure are not limited thereto.

The gate insulation layer 147 may be formed between the second wire pattern 125 and the gate electrode 130. The gate insulation layer 147 may be formed along the circumference of the second wire pattern 125.

The source/drain 150 may be directly connected to the second wire pattern 125. The second wire pattern 120 may be used as a channel region. For example, the source/drain 150 may be directly connected to the first wire pattern 120 and the second wire pattern 125, the second wire pattern 125 having passed the through-hole 140h of the gate spacer 140.

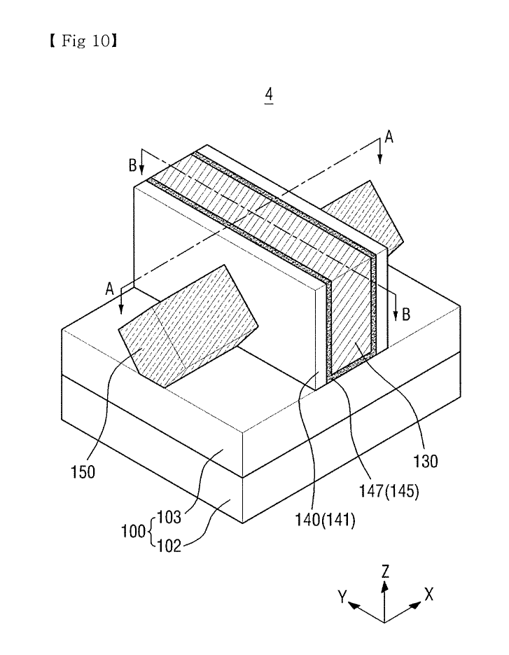

A semiconductor device according to an exemplary embodiment of the present inventive concept will be described with reference to FIGS. 10 to 12. For brevity, the following description will focus on differences between an exemplary embodiment of the inventive concept and the exemplary embodiment of the present inventive concept described with reference to FIGS. 1 to 4B.

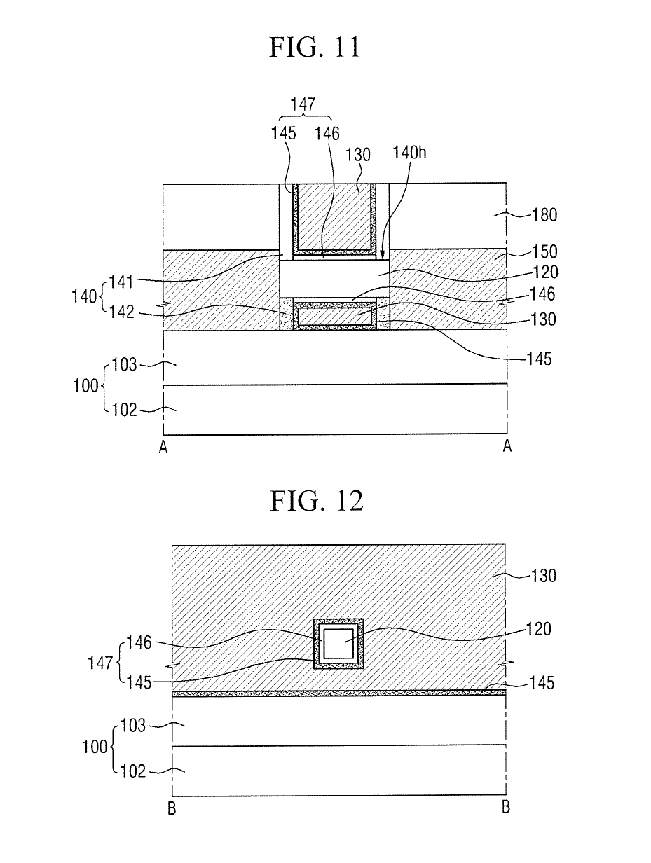

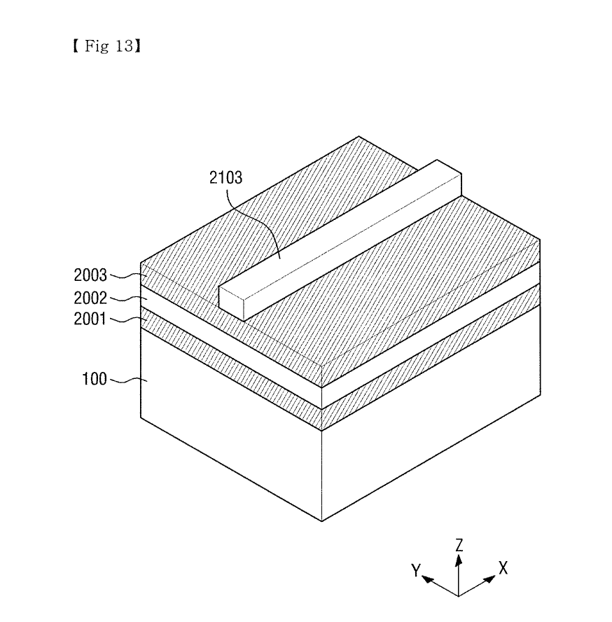

FIG. 10 is a perspective view for explaining a semiconductor device according to an exemplary embodiment of the present inventive concept. FIG. 11 is a cross-sectional view of the semiconductor device shown in FIG. 1, taken along line A-A of FIG. 10, according to an exemplary embodiment of the present inventive concept. FIG. 12 is a cross-sectional view of the semiconductor device shown in FIG. 1, taken along line B-B of FIG. 10, according to an exemplary embodiment of the present inventive concept.

Referring to FIGS. 10 to 12, in a semiconductor device 4, according to an exemplary embodiment of the present inventive concept, a substrate 100 may include a base substrate 102 and a buried insulation layer 103 formed on the base substrate 102.

The base substrate 102 may include the same material as the substrate 100. The buried insulation layer 103 may cover a top surface of the base substrate 102. The buried insulation layer 103 may include an insulating material, which includes, for example, one of oxide, nitride, oxynitride and/or a combination thereof.

In the semiconductor device 4, according to an exemplary embodiment of the present inventive concept, a fin type pattern protruding from the substrate 100 need not be provided.

A first wire pattern 120 may be formed on the buried insulation layer 103 and may be spaced apart from the substrate 100. A gate electrode 130 may surround the first wire pattern 120 on the buried insulation layer 103.

An internal spacer 142 of a gate spacer 140 may be positioned between the first wire pattern 120 and the substrate 100. In the semiconductor device 4, according to an exemplary embodiment of the present inventive concept, the internal spacer 142 may make contact with the buried insulation layer 103.

An interfacial layer 146 of a gate insulation layer 147 may be formed along the circumference of the first wire pattern 120 but is not formed along the circumference of a top surface of the buried insulation layer 103. A high-k insulation layer 145 may be formed along the circumference of the first wire pattern 120 and along the top surface of the buried insulation layer 103.

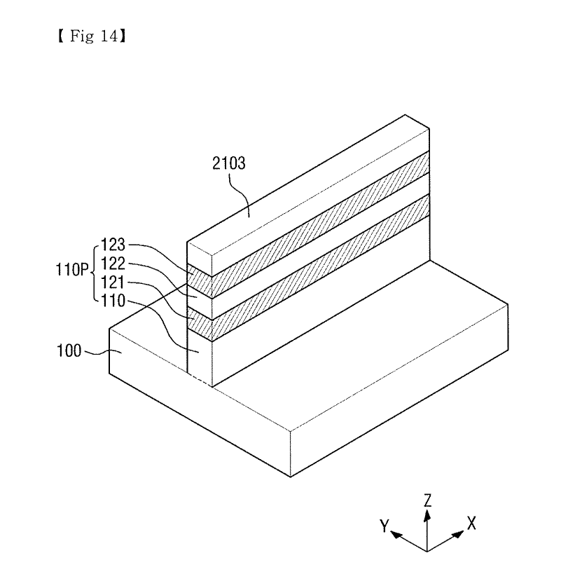

A method of manufacturing a semiconductor device, according to an exemplary embodiment of the present inventive concept, will be described with reference to FIGS. 13 to 23B. The semiconductor device manufactured by the method shown in FIGS. 13 to 23B is the semiconductor device 2 shown in FIGS. 5 to 6B.

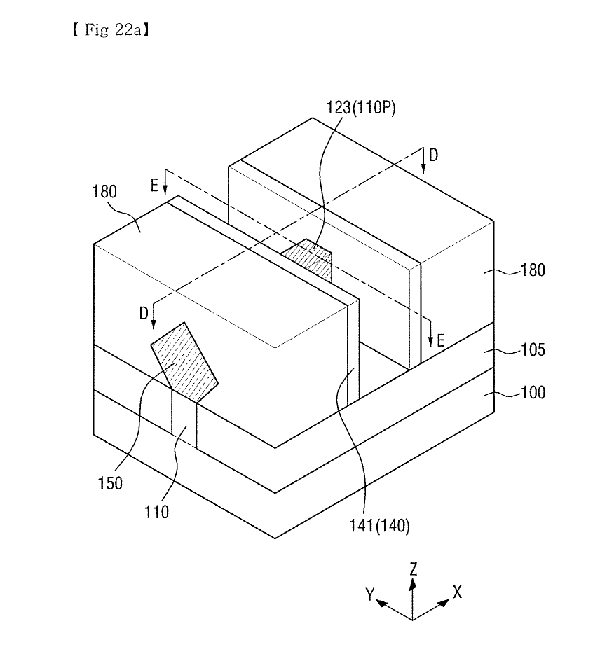

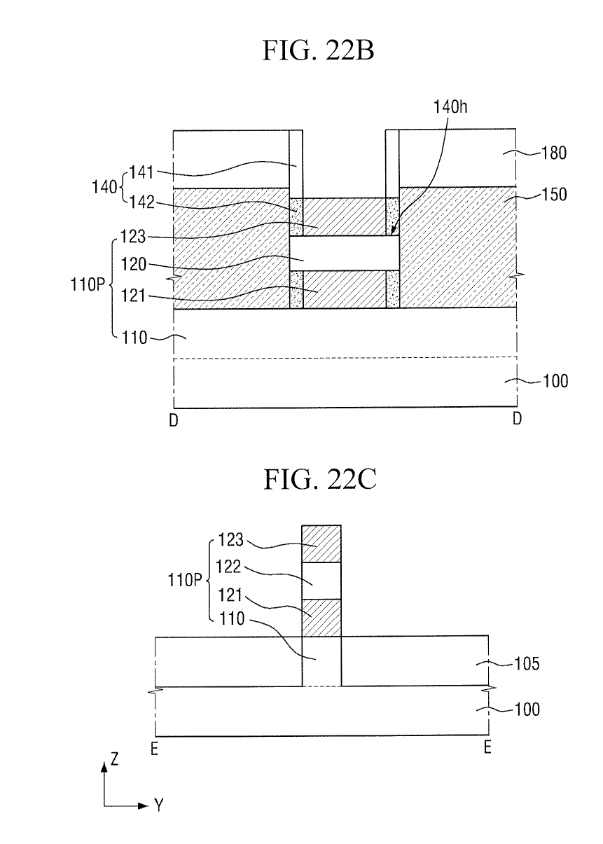

FIGS. 13 to 23B illustrate process steps in a method of manufacturing a semiconductor device according to an exemplary embodiment of the present inventive concept. FIG. 22B is a cross-sectional view taken along the line D-D of FIG. 22A, according to an exemplary embodiment of the present inventive concept. FIG. 22C is a cross-sectional view taken along the line E-E of FIG. 22A, according to an exemplary embodiment of the present inventive concept.

Referring to FIG. 13, a first sacrificial layer 2001, an active layer 2002 and a second sacrificial layer 2003 may be sequentially formed on a substrate 100.

The first sacrificial layer 2001 and the second sacrificial layer 2003 may include a same material. The first sacrificial layer 2001 and the active layer 2002 may include different materials. In the method for manufacturing a semiconductor device, according to an exemplary embodiment of the present inventive concept, the first sacrificial layer 2001 and the second sacrificial layer 2003 may include the same material. In addition, the active layer 2002 may include a material having etching selectivity to the first sacrificial layer 2001.

The substrate 100 and the active layer 2002 may include a material used as a channel region of a transistor. In a case of a PMOS, the active layer 2002 may include a material having high mobility of a hole, and in a case of an NMOS, the active layer 2002 may include a material having high mobility of an electron.

The first sacrificial layer 2001 and the second sacrificial layer 2003 may include a material having a lattice constant and a lattice structure. The materials that may have a lattice constant and a lattice structure may be similar to those of the active layer 2002. For example, the first sacrificial layer 2001 and the second sacrificial layer 2003 may include a semiconducting material or a crystallized metal.

In the method of manufacturing a semiconductor device, according to an exemplary embodiment of the present inventive concept, the active layer 2002 may include silicon. Each of the first sacrificial layer 2001 and the second sacrificial layer 2003 may include silicon germanium.

In FIG. 13, the active layer 2002 may be a single layer. The active layer 2002, as illustrated in FIG. 13, includes a single layer. However, exemplary embodiments of the present inventive concept are not limited thereto. The first sacrificial layer 2001 and the active layer 2002 may alternate with respect to each other to form a pair, and may be repeatedly stacked. A second sacrificial layer 2003 may be formed on the topmost active layer 2002.

FIG. 13 illustrates that the second sacrificial layer 2003 may be positioned (e.g., disposed) on the topmost part of a stacked structure. However, exemplary embodiments of the present disclosure are not limited thereto. For example, the active layer 2002 may also be positioned on the topmost part of a stacked structure.

A first mask pattern 2103 may be formed on the second sacrificial layer 2003. The first mask pattern 2103 may extend lengthwise in a first direction X.

The first mask pattern 2103 may include, for example, at least one of silicon oxide, silicon nitride, and silicon oxynitride.

Referring to FIG. 14, an etching process may be performed using the first mask pattern 2103 as a mask to form a fin type structure 110P.

The fin type structure 110P may be formed by patterning the second sacrificial layer 2003, the active layer 2002, the first sacrificial layer 2001 and portions of the substrate 100.

The fin type structure 110P may be formed on the substrate 100 and may protrude from the substrate 100. The fin type structure 110P may extend in the first direction X, like the first mask pattern 2103.

The fin type structure 110P may include a fin type pattern 110, a first sacrificial pattern 121, a pre-wire pattern 122 and a second sacrificial pattern 123, sequentially stacked on the substrate 100.

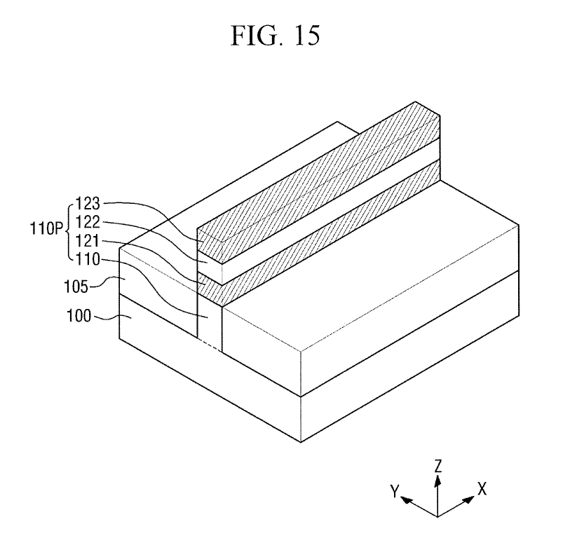

Referring to FIG. 15, a field insulation layer 105, covering at least portions of sidewalls of the fin type structure 110P, may be formed on the substrate 100.

The field insulation layer 105 may cover the fin type structure 110P and may be formed on the substrate 100. Through planarization of the field insulation layer 105, a top surface of the fin type structure 110P and a top surface of the field insulation layer 105 may become coplanar.

In the course of the planarization, the first mask pattern 2103 may be removed. However, exemplary embodiments of the present inventive concept are not limited thereto.

A top portion of the field insulation layer 105 may be recessed to expose a portion of the fin type structure 110P. The recessing process may include a selective etching process. Thus, the fin type structure 110P may extend above the field insulation layer 105.

In FIG. 15 illustrates that the second sacrificial pattern 123, the pre-wire pattern 122, and the first sacrificial pattern 121 may extend above the top surface of the field insulation layer 105. FIG. 15 also illustrates that the sidewalls of the fin type pattern 110 may be entirely surrounded by the field insulation layer 105. However, exemplary embodiments of the present inventive concept are not limited thereto. For example, as a result of recessing the top portion of the field insulation layer 105, portions of the sidewalls of the fin type pattern 110 may extend above the top surface of the field insulation layer 105.

Before and/or after the recessing of the top portion of the field insulation layer 105 to allow a portion of the fin type structure 110P to extend above the field insulation layer 105, doping for adjusting a threshold voltage may be performed on the pre-wire pattern 122. If the semiconductor devices 1 to 4 are NMOS transistors, doping impurity may include boron (B). If the semiconductor devices 1 to 4 are PMOS transistors, doping impurity may include phosphorus (P) or arsenic (As). However, exemplary embodiments of the present inventive concept are not limited thereto.

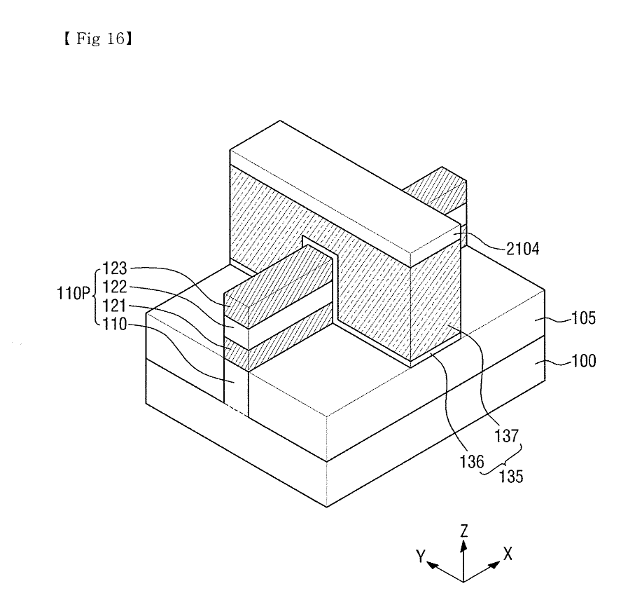

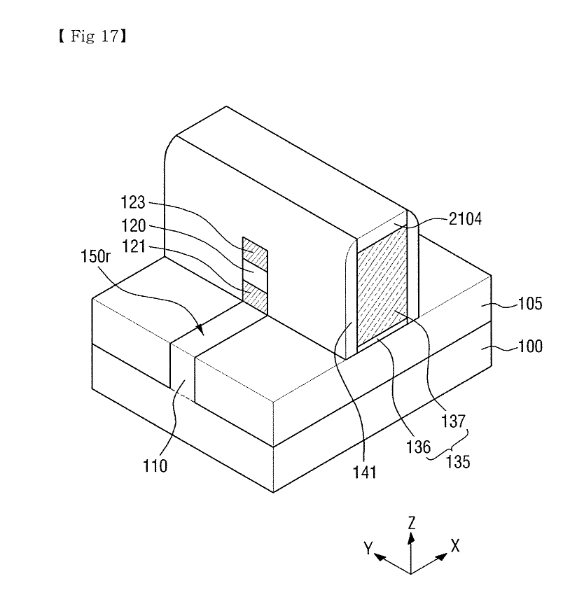

Referring to FIG. 16, an etching process may be performed using the second mask pattern 2104, to form a dummy gate pattern 135. The dummy gate pattern 135 may extend in a second direction Y and may cross the fin type structure 110P. The dummy gate pattern 135 may be formed on the fin type structure 110P.

The dummy gate pattern 135 may include a dummy gate insulation layer 136 and a dummy gate electrode 137. The dummy gate insulation layer 136 may include silicon oxide and the dummy gate electrode 137 may include polysilicon or amorphous silicon.

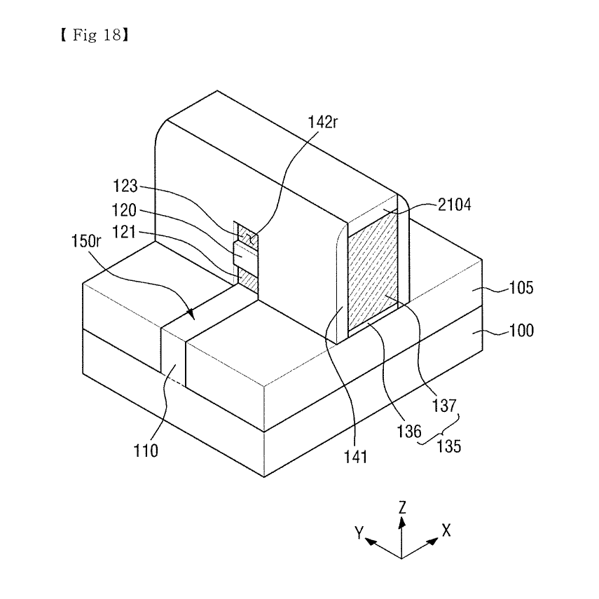

Referring to FIG. 17, an external spacer 141 may be formed on sidewalls of the dummy gate pattern 135. For example, the external spacer 141 may be formed on sidewalls of the dummy gate insulation layer 136 and the dummy gate electrode 137.

The external spacer 141 may result from a first spacer layer covering the dummy gate pattern 135 and the fin type structure 110P on the field insulation layer 105. The first spacer layer may be etched to form the external spacer 141 on the sidewalls of the dummy gate pattern 135.

The fin type structure 110P, not overlapping with the dummy gate electrode 137 and the external spacer 141, may be removed using the dummy gate pattern 135 including the dummy gate electrode 137 as a mask. As the result, a recess 150r may be formed in the fin type structure 110P. A bottom surface of the recess 150r may correspond to the fin type pattern 110.

Forming the external spacer 141 and forming the recess 150r may be simultaneously performed. However, exemplary embodiments of the present inventive concept are not limited thereto. For example, after forming the external spacer 141, the recess 150r may be formed by removing a portion of the fin type structure 110P.

When forming the recess 150r in the fin type structure 110P, the first sacrificial pattern 121, the second sacrificial pattern 123, not overlapping with the dummy gate electrode 137, and the external spacer 141 may be removed. Also, when forming the recess 150r in the fin type structure 110P, the pre-wire pattern 122, not overlapping with the dummy gate electrode 137, and the external spacer 141 may be removed. Accordingly, the first wire pattern 120 may be formed.

The recess 150r may expose a cross-section of the first sacrificial pattern 121, a cross-section of the second sacrificial pattern 123 and a cross-section of a first wire pattern 120. The first wire pattern 120 may correspond to the pre-wire pattern 122.

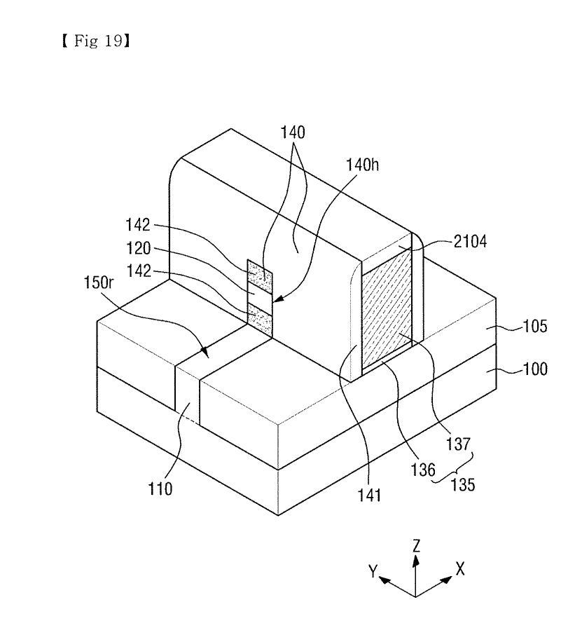

Referring to FIG. 18, at least a portion of the first sacrificial pattern 121 and at least a portion of the second sacrificial pattern 123, exposed by the recess 150r and overlapping with the external spacer 141, may be removed. As a result, a dimple 142r may be formed between the external spacer 141 and the first wire pattern 120.

The dimple 142r may be shaped such that it is recessed in the first direction X. The dimple 142r may expose the first wire pattern 120 on a cross-sectional view of the first wire pattern 120.

The dimple 142r may be formed by, for example, a selective etching process. For example, the dimple 142r may be formed by an etching process using an etchant having a higher etching rate on the first sacrificial pattern 121 and on the second sacrificial pattern 123 than on the first wire pattern 120.

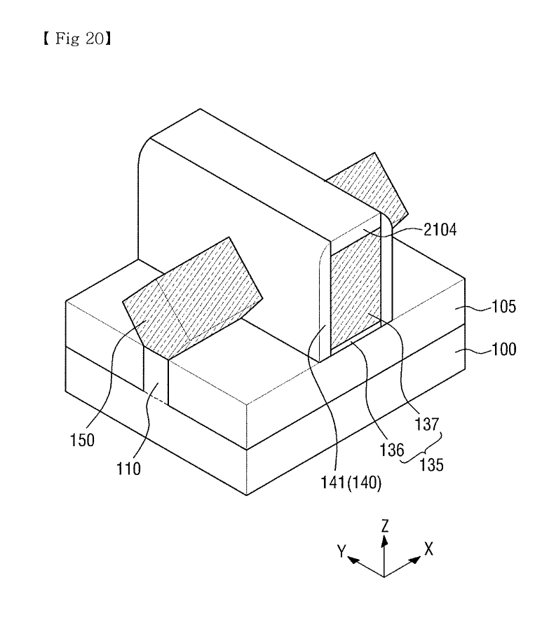

Referring to FIG. 19, the dimple 142r may be filled with an insulating material to form the internal spacer 142.

The internal spacer 142 may be formed according to the following: A second spacer layer may filling the dimple 142r. The second spacer layer may include a material having a good gap-filling characteristic. The second spacer layer may also be formed on the field insulation layer 105, on the sidewalls of the external spacer 141 and on the dummy gate pattern 135.

An etching process may be performed to etch the second spacer layer to the top surface of the fin type pattern 110, not overlapping with the dummy gate pattern 135 and exposing the external spacer 141. Thus, the internal spacer 142 may be formed.

As the result, a gate spacer 140, including the external spacer 141 and the internal spacer 142, may be formed.

In addition, a through-hole 140h, defined by the external spacer 141 and the internal spacer 142, may be formed on the gate spacer 140. The through-hole 140h may expose the first wire pattern 120. For example, the first wire pattern 120 may pass through the through-hole 140h.

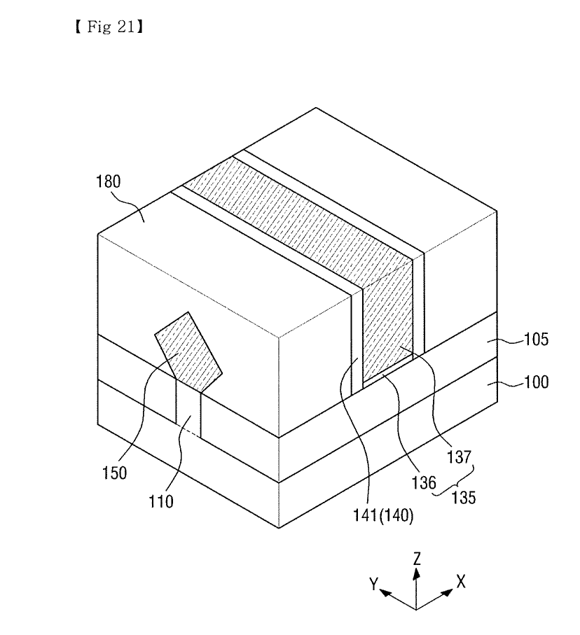

Referring to FIG. 20, a source/drain 150 filling the recess 150r may be formed. The source/drain 150 may be formed at opposite sides of the dummy gate pattern 135.

The source/drain 150 may be formed using the exposed fin type pattern 110 and the first wire pattern 120 as seed layers. However, exemplary embodiments of the present inventive concept are not limited thereto. Further, a seed layer may be formed on a cross-section of the first wire pattern 120 exposed by the recess 150r, and on the fin type pattern 110.

The source/drain 150 may be formed to cover the internal spacer 142. The source/drain 150 may be in contact with the internal spacer 142.

The source/drain 150 may be formed by an epitaxial process. The material of the epitaxial layer included in the source/drain 150 may vary according to whether the semiconductor devices 1 to 4, according to the exemplary embodiments of the present inventive concept, are n type transistors or p type transistors. When necessary, impurity may be in situ doped during the epitaxial process.

Referring to FIG. 21, an interlayer insulating layer 180 may be formed on the field insulation layer 105. The interlayer insulating layer 180 may cover the source/drain 150, the gate spacer 140 and the dummy gate pattern 135.

The interlayer insulating layer 180 may include, for example, at least one of a low-k material, an oxide layer, a nitride layer and an oxynitride layer. Examples of the low-k material may include flowable oxide (FOX), Tonen silazene (TOSZ), undoped silicate glass (USG), borosilica glass (BSG), phosphosilaca glass (PSG), borophosphor silica glass (BPSG), plasma enhanced tetraethyl orthosilicate (PETEOS), fluoride silicate glass (FSG), high density plasma (HDP) oxide, plasma enhanced oxide (PEOX), flowable chemical vapor deposition (FCVD), or combinations thereof. However exemplary embodiments of the present inventive concept are not limited thereto.

Until a top surface of the dummy gate electrode 137 is exposed, the interlayer insulating layer 180 may be planarized. As a result, the second mask pattern 2104 may be removed and the top surface of the dummy gate electrode 137 may be exposed.

Referring to FIGS. 22A to 22C, the dummy gate pattern 135, which includes a dummy gate insulation layer 136 and a dummy gate electrode 137, may be removed.

When the dummy gate insulation layer 136 and the dummy gate electrode 137 are removed, the fin type structure 110P, overlapping with the field insulation layer 105 and the dummy gate pattern 135, may be exposed. For example, the first sacrificial pattern 121 overlapping with the dummy gate pattern 135, the second sacrificial pattern 123 and the first wire pattern 120 may be exposed.

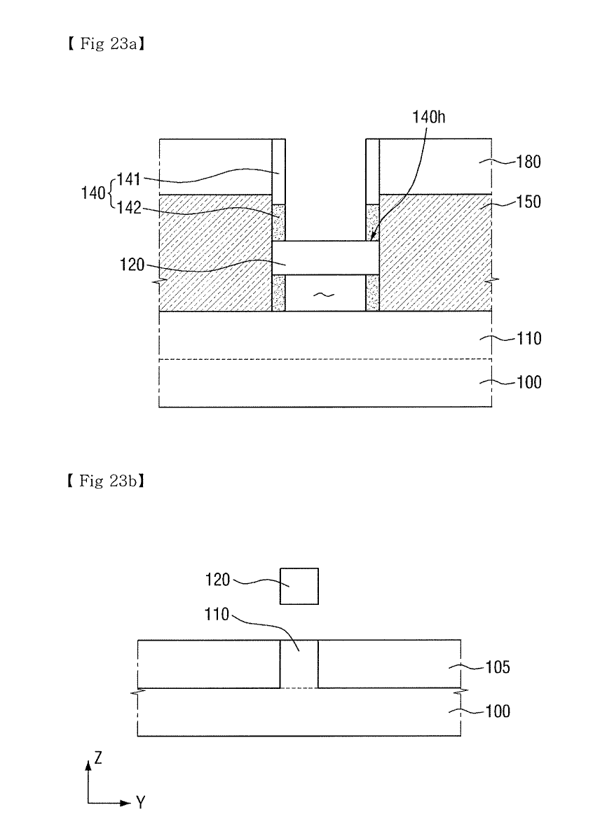

Referring to FIGS. 23A and 23B, the first sacrificial pattern 121 and the second sacrificial pattern 123 of the fin type structure 110P may be removed.

As the result, a space may be produced between the first wire pattern 120 and the fin type pattern 110. In addition, the first wire pattern 120 may be formed on the fin type pattern 110.

The removing of the first sacrificial pattern 121 and the second sacrificial pattern 123 positioned on and under the first wire pattern 120 may be performed by, for example, etching. Etching selectivity with respect to each of the first sacrificial pattern 121, the second sacrificial pattern 123 and the first wire pattern 120 may be used in the etching.

In addition, as the first sacrificial pattern 121 and the second sacrificial pattern 123 are removed, the internal spacer 142 of the gate spacer 140 may be exposed.

Referring to FIG. 5, an interfacial layer 146 may be formed on the circumference of the first wire pattern 120 and on the top surface of the fin type pattern 110.

A high-k insulation layer 145 may be formed along sidewalls of the gate spacer 140. The gate spacer 140 includes sidewalls of the external spacer 141 and sidewalls of the internal spacer 142. The high-k insulation layer 145 may be formed along the circumference of the first wire pattern 120. The high-k insulation layer 145 may be in contact with the internal spacer 142. Accordingly, a gate insulation layer 147 may be formed.

A gate electrode 130 surrounding the first wire pattern 120 and extending in the second direction Y may be formed. The gate electrode 130 may be a replacement metal gate electrode.

FIG. 24 is a block diagram of an electronic system including semiconductor devices according to exemplary embodiments of the present inventive concept.

Referring to FIG. 24, the electronic system 1100 may include a controller 1110, an input/output device (I/O) 1120, a memory 1130, an interface 1140 and a bus 1150. The controller 1110, the I/O 1120, the memory 1130, and/or the interface 1140 may be connected to each other via the bus 1150. The bus 1150 may correspond to a path through which data moves.

The controller 1110 may include at least one of a microprocessor, a digital signal processor, a microcontroller, and logic elements capable of functioning similarly to a microprocessor, a digital signal processor, or microcontroller. The I/O 1120 may include a keypad, a keyboard, a display device, and the like. The memory 1130 may store data and/or commands. The interface 1140 may transmit data to a communication network or receive data from the communication network. The interface 1140 may be wired or wireless. For example, the interface 1140 may include an antenna or a wired/wireless transceiver, and the like.

The electronic system 1100 may further include high-speed dynamic random access memory (DRAM) and/or static random access memory (SRAM) as the working memory for improving the operation of the controller 1110. The semiconductor devices according to embodiments of the present inventive concept may be provided in the memory 1130 or may be provided some components of the controller 1110 or the I/O 1120.

The electronic system 1100 may be used in a personal digital assistant (PDA), a portable computer, a web tablet, a wireless phone, a mobile phone, a digital music player, a memory card, or any type of electronic device capable of transmitting and/or receiving information in a wireless environment.

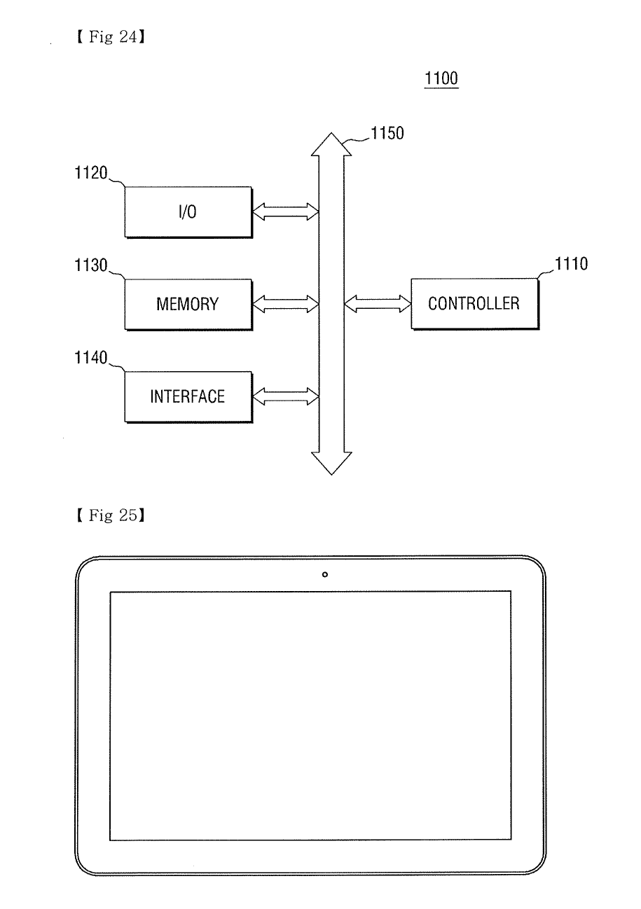

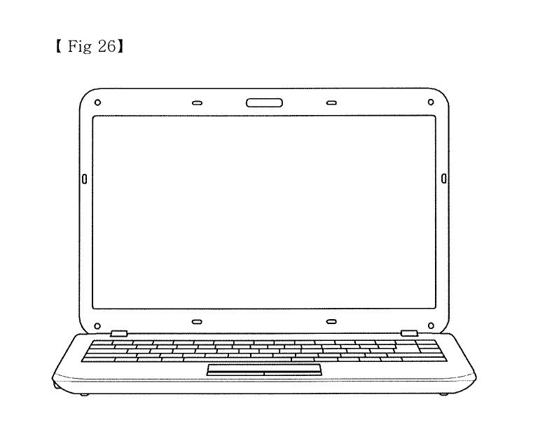

FIGS. 25 and 26 illustrate exemplary semiconductor systems that may use semiconductor devices, according to one or more exemplary embodiments of the present inventive concept. For example, FIG. 25 illustrates an example in which a semiconductor device, according to an exemplary embodiment of the present inventive concept, is used in a tablet personal computer (PC). FIG. 26 illustrates an example in which a semiconductor device, according to an exemplary embodiment of the present inventive concept, is used in a notebook computer. It may be obvious to one skilled in the art that semiconductor devices, according to some exemplary embodiments of the present inventive concept, may also be applied to other integrated circuit (IC) devices not illustrated herein.

While the present inventive concept has been particularly described with reference to exemplary embodiments thereof, it will be understood by those of ordinary skill in the art that various changes in form and detail may be made to the exemplary embodiments of the present inventive concept without departing from the spirit and scope of the present inventive concept.

1. A semiconductor device, comprising:
a first wire pattern formed on a substrate and spaced apart from the substrate, the first wire pattern extending in a first direction, wherein the substrate includes a fin type active pattern protruding therefrom;
a gate electrode surrounding a circumference of the first wire pattern and extending in a second direction, wherein the second direction crosses the first direction;
source and drain regions connected to the first wire pattern at opposite sides of the gate electrode; and
a gate spacer disposed on opposite sidewalls of the gate electrode, the gate spacer including a first part and a second part,
wherein the first part includes a top portion and a bottom portion spaced apart from each other,
wherein the second part is disposed at opposite sides of the first part in the second direction,
wherein the second part directly contacts the bottom portion of the first part, and
wherein a bottom surface of at least one of the source and drain regions, a bottom surface of the bottom portion of the first part of the gate spacer and a top surface of the fin type active pattern occupy a common plane.

2. The semiconductor device of claim 1, wherein the first wire pattern passes through the first part of the gate spacer.

3. The semiconductor device of claim 1, wherein the top portion of the first part of the gate spacer includes a material having a first dielectric constant and the bottom portion of the first part of the gate spacer includes a material having a second dielectric constant, wherein the second dielectric constant is different from the first dielectric constant.

4. The semiconductor device of claim 1, wherein the top portion of the first part of the gate spacer and the second part of the gate spacer form an integral structure.

5. The semiconductor device of claim 1, wherein a topmost part of the first wire pattern contacts the top portion of the first part of the gate spacer and a bottommost part of the first wire pattern contacts the bottom portion of the first part of the gate spacer.

6. The semiconductor device of claim 1, further comprising a second wire pattern disposed on the substrate and spaced apart from the substrate, wherein a first distance between the second wire pattern and the substrate is greater than a second distance between the first wire pattern and the substrate,
wherein the bottom portion of the first part of the gate spacer is disposed between the first wire pattern and the second wire pattern.

7. The semiconductor device of claim 1,
wherein at least one of the source and drain regions includes an epitaxial layer.

8. The semiconductor device of claim 1, further comprising a gate insulation layer formed along the circumference of the first wire pattern and sidewalls of the gate spacer.

9. The semiconductor device of claim 8,
wherein at least one of the source and drain regions does not contact the gate insulation layer.

10. The semiconductor device of claim 1, wherein the gate spacer includes a through-hole, wherein the first wire pattern passes through the through-hole,
wherein first sides facing each other in the second direction in the through-hole are defined by the second part of the gate spacer, and
wherein at least one of second sides connecting the first sides in the through-hole is defined by the bottom portion of the first part of the gate spacer.

11. A semiconductor device, comprising:
a wire pattern formed on a substrate and spaced apart from the substrate, the wire pattern extending in a first direction;
a gate electrode surrounding a circumference of the wire pattern and extending in a second direction, wherein the second direction crosses the first direction;
source and drain regions connected to the first wire pattern at opposite sides of the gate electrode;
a gate spacer disposed on opposite sidewalls of the gate electrode, the gate spacer contacting the entire circumference of a termination part of the wire pattern; and
a gate insulation layer formed along the circumference of the wire pattern and sidewalls of the gate spacer,
wherein a bottom surface of at least one of the source and drain regions, a bottom surface of the gate spacer and a top planar surface of the substrate occupy a same plane.

12. The semiconductor device of claim 11, wherein the gate spacer comprises a first part including a material having a first dielectric constant and a second part including a material having a second dielectric constant, wherein the second dielectric constant is smaller than the first dielectric constant.

13. The semiconductor device of claim 12, wherein the wire pattern contacts the second part of the gate spacer.

14. The semiconductor device of claim 11, wherein the gate spacer includes a through-hole, wherein the wire pattern passes through the through-hole.

15. The semiconductor device of claim 11, wherein the wire pattern extends in the first direction past the gate insulation layer formed on the sidewalls of the gate electrode.

16. A semiconductor device, comprising:
a wire pattern extending in a first direction and spaced apart from a substrate;
a gate electrode extending in a second direction that crosses the first direction, the gate electrode surrounding a circumference of the wire pattern;
source and drain regions connected to the first wire pattern at opposite sides of the gate electrode; and
a gate spacer disposed on opposite termination parts of the wire pattern, the gate spacer including a through-hole, wherein at least one of the opposite termination parts of the wire pattern passes through the through-hole,
wherein the substrate includes a fin type active pattern, and wherein and end of at least one of the source and drain regions, and end of the gate spacer and an end of the fin type active pattern are co-planar with respect to each other.

17. The semiconductor device of claim 16, wherein the gate spacer comprises a first part and a second part,
wherein the first part includes a top portion and a bottom portion spaced apart from each other,
wherein the second part is disposed in the second direction at opposite sides of the first part, and
wherein the second part directly contacts the bottom portion of the first part.

18. The semiconductor device of claim 17, wherein the top portion of the first part of the gate spacer includes a material having a first dielectric constant and the bottom portion of the first part of the gate spacer includes a material having a second dielectric constant, wherein the second dielectric constant is different from the first dielectric constant.

19. The semiconductor device of claim 17, wherein the top portion of the first part of the gate spacer and the second part of the gate spacer form a connected structure.

20. The semiconductor device of claim 16, further comprising a gate insulation layer formed along the circumference of the wire pattern and sidewalls of the gate spacer,
wherein the wire pattern extends in the first direction past the gate insulation layer formed on the sidewalls of the gate electrode.
